(19) United States
(12) Patent Application Publication
(10) Pub. No.: US 2021/0053177 A1
(43) Pub. Date: Feb. 25, 2021

(54) SYSTEM, DEVICE AND METHOD FOR RECONDITIONING A SUBSTRATE SUPPORT

(71) Applicants: ASML NETHERLANDS B.V., Veldhoven (NL); ASML HOLDING N.V., Veldhoven (NL)

(72) Inventors: Bert Dirk SCHOLTEN, Best (NL); Satish ACHANTA, Leuven (BE); Aydar AKCHURIN, Eindhoven (NL); Pavlo ANTONOV, Valkenburg (ZH) (NL); Coen Hubertus Matheus BALTIS, Eindhoven (NL); Jeroen BOUWKNEGT, Tilburg (NL); Ann-Sophie m. FARLE, Eindhoven (NL); Christopher John MASON, Newtown, CT (US); Ralph Nicholas PALERMO, Stratford, CT (US); Thomas POIESZ, Veldhoven (NL); Yuri Johannes Gabriel VAN DE VIJVER, Best (NL); Jimmy Matheus Wilhelmus VAN DE WINKEL, Kessel (NL)

(73) Assignees: ASML NETHERLANDS B.V., Veldhoven (NL); ASML HOLDING N.V., Veldhoven (NL)

(21) Appl. No.: 16/963,576

(22) PCT Filed: Jan. 24, 2019
(86) PCT No.: PCT/EP2019/051767

§ 371 Date: Jul. 21, 2020

Related U.S. Application Data
(60) Provisional application No. 62/627,177, filed on Feb. 6, 2018.

(51) Int. Cl. B24B 27/033; B24B 1/04; B24B 7/07; B24B 7/22; G03F 7/20; H01L 21/304

(52) U.S. Cl. CPC B24B 27/033; B24B 1/04; B24B 7/075; H01L 21/304; G03F 7/70691; G03F 7/70925; B24B 7/22

(57) ABSTRACT

A treatment tool for reconditioning the top surfaces of a plurality of projections of a substrate support in a lithographic tool. The treatment tool includes a reconditioning surface which is rough relative to smoothed top surfaces of the projections and which reconditioning surface has material harder than that of the material of the top surfaces of the projections. A reconditioning method involves causing an interaction between the reconditioning surface of the treatment tool and the top surfaces of the projections of the substrate support, so as to leave these top surfaces rougher than they were prior to the interaction.

### CROSS-REFERENCE TO RELATED APPLICATIONS

This application claims priority of U.S. application 62/627,177 which was filed on 6 Feb. 2018 and which is incorporated herein in its entirety by reference.

### FIELD

The present description relates to a device for reconditioning a substrate support for holding a substrate, such as a semiconductor wafer. The present description further relates to a system and a method in which such a device is used.

### BACKGROUND

A lithographic apparatus is a machine constructed to apply a desired pattern onto a substrate. Such a lithographic apparatus can be used, for example, in the manufacture of integrated circuits (ICs). A lithographic apparatus may, for example, project a pattern (often referred to as “design layout” or “design”) of a patterning device (e.g., a mask) onto a layer of radiation-sensitive material (resist) provided on a substrate (e.g., a wafer). To project the pattern on the substrate the lithographic apparatus may use radiation, such as electromagnetic radiation. Typical wavelengths of such radiation currently in use are about 365 nm, about 248 nm, about 193 nm (deep ultraviolet (DUV) radiation) and 13.5 nm (extreme ultraviolet (DUV) radiation).

The substrate (e.g., a wafer such as a semiconductor wafer) is clamped onto a substrate support of a substrate table (e.g., a wafer table) in the lithographic apparatus when transferring the pattern from the patterning device. Such a substrate support can have a plurality of projections (called burls) extending in a first (z) direction to support the substrate. The total area of the top surfaces of the projections that contact the substrate, thereby to support the substrate, is small compared to the total area of the substrate. Because of this, the chance that a contaminant particle randomly located on the surface of the substrate or the substrate support is trapped between a projection and the substrate is small. Also, in manufacture of the substrate support, the tops of the plurality of projections can be made more accurately coplanar than a large surface can be made accurately flat.

To achieve a desired precision during, for example, the manufacture of integrated circuits (ICs), a substrate support of a substrate table should exhibit a high mechanical and thermal stability. Therefore substrate supports are often made of a ceramic, such as silicon carbide (SiC), which has desirable properties, such as low density, low thermal expansion coefficient and high thermal conductivity.

When the substrate is first loaded onto the substrate support of the substrate table in preparation for exposure, the substrate is supported by so-called e-pins which hold the substrate at multiple positions. To load the substrate onto the substrate support, the e-pins are retracted so that the substrate is then supported by the plurality of projections (called burls) of the substrate support.

### SUMMARY

It is desirable that the substrate lies flat on the substrate support. Otherwise the pattern projected onto the layer of radiation-sensitive material (resist) provided on the substrate may be out of focus (resulting in a so-called focus error). Furthermore, lithography may involve multiple projections of patterns on a single substrate over time. It is desirable that the substrate is precisely re-aligned on the substrate support relative to its position during a prior projection. Incorrect alignment during any of the subsequent projections may result in a so-called overlay error.

Therefore, the flatness of the plurality of projections (i.e., how close all of the top surfaces of the projections are to being in the same plane) is significant. This is because any variation in the flatness of the projections is transmitted to the top surface of the substrate which is subjected to irradiation. As an example, the flatness of the substrate can be reduced if there is contamination between the top surface of a projection and the substrate.

To remove this contamination from the substrate support, the substrate support is periodically cleaned by moving a treatment tool over the top surfaces of the plurality of projections in directions orthogonal to the first (z) direction. One such treatment tool is disclosed in PCT Patent Application Publication No. WO 2016/081951, which is incorporated herein in its entirety by reference, which describes a disc (or puck) which is moved over the substrate support and may be rotated at the same time as it is moved over the substrate support. The footprint of this disc (or puck) is smaller than that of the substrate support so that the substrate support and disc (or puck) are moved relative to one another during the treatment. The treatment tool for removing the contamination may be made, for example, of granite or of a composite material of silicon and silicon carbide (SiSiC) or monolithic material like CVD SiC.

A perfect loading of a substrate onto a substrate support implies that no strain remains in the loaded substrate once it fully lies on (and is clamped to) the plurality of projections (called burls) of the substrate support. Any strain locked into the substrate may deform the substrate in directions orthogonal to the first (z) direction (i.e., the xy plane) and thereby cause overlay errors. Local sliding of the substrate may take place when loading the substrate onto the substrate support. The residual deformations in the substrate caused by this local sliding contributes to the overlay error. A metric for quantifying the error introduced by this deformation is a so-called Wafer Load Grid (WLG).

It has been observed that applying the treatment tool described above to a substrate support in order to remove contamination and/or restore the desired flatness of the plurality of projections may lead to a higher Wafer Load Grid (WLG) and thereby to higher overlay errors.

It is desirable to provide an improved treatment tool for removing contamination and maintaining the flatness of a substrate support, while at the same time maintaining, or even reducing, the Wafer Load Grid (WLG) effect. It is further desirable to provide an improved treatment tool for a substrate support which reduces a Wafer Load Grid (WLG) effect already present, thereby reconditioning the substrate support.

According to an aspect, there is provided an improved treatment tool for reconditioning top surfaces of a plurality of projections of a substrate support, the improved treatment tool comprising a reconditioning surface which is rough relative to the top surfaces of the projections and which reconditioning surface comprises material harder than that of the material of the top surfaces of the projections. According to this aspect the reconditioning surface of the improved treatment tool is rough relative to the top surfaces of the substrate support to be treated by the improved treatment tool (that is, the original roughness of the top surfaces of the projections or the roughness of the smoothed top surfaces of the projections when the substrate support has been contaminated during use).

According to an aspect, there is provided a reconditioning method, the reconditioning method causing an interaction between the reconditioning surface of the improved treatment tool and the top surfaces of the projections, thereby leaving these top surfaces rougher than they were prior to the interaction.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 schematically depicts a lithographic apparatus comprising a substrate support;

FIG. 2 depicts, in plan, a substrate support with a superimposed treatment tool;

FIG. 3 depicts a surface of a substrate support before and after reconditioning with an embodiment of the improved treatment tool as described herein;

FIG. 4 depicts a structure of a surface of an embodiment of the improved treatment tool as described herein;

FIG. 5 schematically illustrates an embodiment of a regeneration method for reconditioning a substrate support;

FIG. 6 is a schematic illustration of a system for cleaning a substrate support; and

FIG. 7 shows an embodiment of the improved treatment tool according to an embodiment.

### DETAILED DESCRIPTION

In the present document, the terms “radiation” and “beam” are used to encompass all types of radiation, including radiation with, e.g., a wavelength of about 365, about 248, about 193, about 157, about 126 or about 13.5 nm.

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

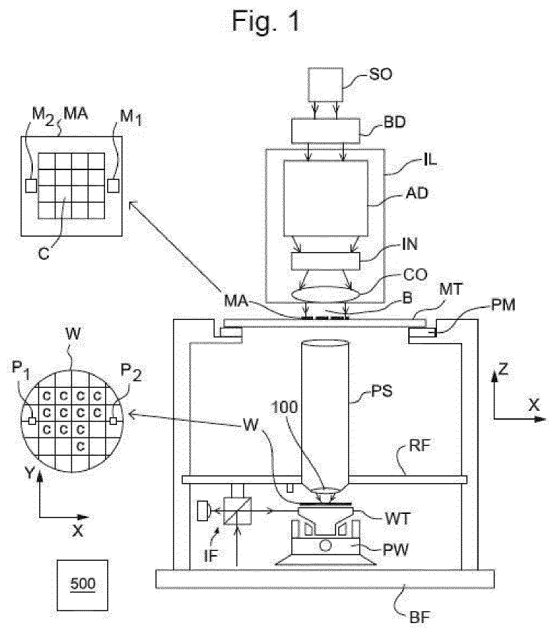

FIG. 1 schematically depicts a lithographic apparatus of an embodiment. The apparatus comprises:
optionally, an illumination system (illuminator) IL configured to condition a radiation beam B (e.g. UV radiation, DUV radiation or EUV radiation);
a support structure (e.g. a mask table) MT constructed to support a patterning device (e.g. a mask) MA and connected to a first positioner PM configured to accurately position the patterning device MA in accordance with certain parameters;
a substrate table WT, e.g. wafer table, constructed to hold a substrate (e.g. a resist-coated semiconductor wafer) W, connected to a second positioner PW configured to accurately position the surface of the table, for example of the substrate W, in accordance with certain parameters; and
a projection system (e.g. a refractive projection lens system) PS configured to project a pattern imparted to the radiation beam B by patterning device MA onto a target portion C (e.g. comprising part of, one, or more dies) of the substrate W. The projection system can be supported on a reference frame RF, which can in turn be supported on a base frame BF.

The lithographic apparatus may be of a type wherein at least a portion of the substrate W may be covered by an immersion liquid having a relatively high refractive index, e.g. water such as ultra pure water (UPW), so as to fill an immersion space between the projection system PS and the substrate W. An immersion liquid may also be applied to other spaces in the lithography apparatus, for example, between the patterning device MA and the projection system PS. The term “immersion” as used herein does not mean that a structure, such as a substrate W, must be submerged in immersion liquid; rather “immersion” only means that an immersion liquid is located between the projection system PS and the substrate W during exposure. The path of the patterned radiation beam B from the projection system PS to the substrate W is entirely through immersion liquid.

In operation, the illuminator IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA using, for example, adjuster AD. In addition, the illuminator IL may comprise various other components, such as an integrator IN and a condenser CO.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum.

The lithographic apparatus may be of a type having two or more substrate tables, e.g., two or more substrate tables or a combination of one or more substrate tables and one or more cleaning, sensor or measurement tables. For example, the lithographic apparatus can be a multi-stage apparatus comprising two or more tables located at the exposure side of the projection system, each table comprising and/or holding one or more objects. In an example, one or more of the tables may hold a radiation-sensitive substrate. In an example, one or more of the tables may hold a sensor to measure radiation from the projection system. In an example, the multi-stage apparatus comprises a first table configured to hold a radiation-sensitive substrate (i.e., a substrate table) and a second table not configured to hold a radiation-sensitive substrate (referred to hereinafter generally, and without limitation, as a measurement, sensor and/or cleaning table). The second table may comprise and/or may hold one or more objects, other than a radiation-sensitive substrate. Such one or more objects may include one or more selected from the following: a sensor to measure radiation from the projection system, one or more alignment marks, and/or a cleaning device (to clean, e.g., the liquid confinement structure).

In operation, the radiation beam B is incident on the pattern (design layout) portion of patterning device (e.g., mask) MA, which is held on the support structure (e.g., mask table) MT, and is patterned by the patterning device MA. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. so as to position different target portions C in the path of the radiation beam B at a focused and aligned position. Similarly, the first positioner PM and another position sensor (which is not explicitly depicted in FIG. 1) can be used to accurately position the patterning device MA with respect to the path of the radiation beam B. Patterning device MA and substrate W may be aligned using patterning device alignment marks M1, M2 and substrate alignment marks P1, P2. Although the substrate alignment marks P1, P2 as illustrated occupy dedicated target portions, they may be located in spaces between target portions C (these are known as scribe-lane alignment marks). A controller 500 controls the overall operations of the lithographic apparatus and in particular performs an operation process described further below.

The substrate table WT comprises a substrate support 60. The substrate W is conventionally clamped to the substrate support 60 during exposures. Two clamping techniques are commonly used. In vacuum clamping, a pressure differential across the substrate W is established, e.g., by connecting the space between the substrate support 60 and the substrate W to an under-pressure that is lower than a higher pressure above the substrate W. The pressure difference gives rise to a force holding the substrate W to the substrate support 60. In electrostatic clamping, electrostatic forces are used to exert a force between the substrate W and the substrate support 60.

To load a substrate W onto the substrate support 60 for exposures, the substrate W is picked up by a substrate handler robot and lowered onto a set of e-pins. The e-pins project through the substrate support 60. The e-pins are actuated so that they can extend and retract. The e-pins may be provided with suction openings at their tips to grip the substrate W. Once the substrate W has settled on the e-pins, the e-pins are retracted so that the substrate W is supported by projections 20 of the substrate support 60.

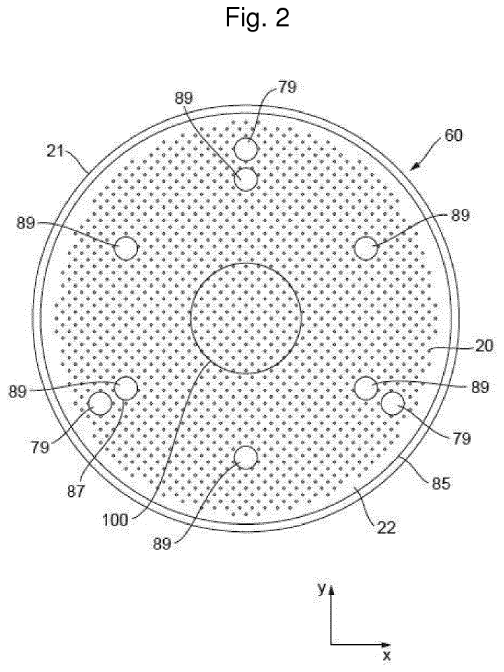

FIG. 2 depicts an embodiment of a substrate support 60 for use in, e.g., a lithographic apparatus. The substrate support 60 supports a substrate W. The substrate support 60 comprises a main body 21. The main body 21 has a main body surface 22. A plurality of projections 20 are provided projecting from the main body surface 22 in the first (z) direction. A top surface of each projection 20 engages (contacts) with the substrate W. The top surfaces of the projections 20 substantially conform to a support plane and support the substrate W. Main body 21 and projections 20 may be formed of silicon carbide (SiC). Main body 21 and projections 20 may be formed of SiSiC, a ceramic material having silicon carbide (SiC) grains in a silicon matrix. To improve the tribological behavior of the top surfaces of these projections 20 they may be coated with a diamond like carbon (DLC) or perfluoropolyether (PFPE) coating.

A plurality of through-holes 89 may be formed in the main body 21. Through-holes 89 allow the e-pins to project through the substrate support 60 to receive the substrate W. Through-holes 89 may allow the space between the substrate W and the substrate support 60 to be evacuated. Evacuation of the space between the substrate W and the substrate support 60 can provide a clamping force, if the space above the substrate W is not also evacuated. The clamping force holds the substrate W in place. If the space above the substrate W is also evacuated, as would be the case in a lithographic apparatus using EUV radiation, electrodes can be provided on the support 60 WT to form an electrostatic clamp.

Further through-holes 79 are illustrated in FIG. 2. Such through-holes may be present, for example, to allow the substrate support 60 to be fixed to the substrate table WT, for example using bolts. In an embodiment, the substrate support 60 can be fixed to substrate table WT by vacuum clamping.

During cleaning of the substrate support 60 with a treatment tool 100 as disclosed in PCT Patent Application Publication No. WO 2016/081951, the treatment tool 100 is supported on the terminal surfaces of the projections 20. FIG. 2 shows a disc shaped treatment tool 100 superimposed over the substrate support 60.

The interface between the substrate W and the substrate support is through a large number of the small projections 20 (or burls) of the substrate support 60. These projections may, for instance, have a diameter of about 300 μm and a pitch between them of about 2.5 mm and/or a diameter of about 210 μm and a pitch between them of about 1.5 mm. The tribological behavior of the top surfaces of these projections 20 is significant to clamping the substrate W without locking in significant strain which may distort the substrate W and cause overlay errors. Modeling of the interactions of the top surfaces of the projections 20 and the substrate W in a WLG model has shown that the frictional characteristics of the top surfaces of the projections 20 are significant. Greater frictional forces lock strain into the clamped substrate W, leading to the distortion of this substrate.

Cleaning the top surfaces of the projections 20 with a treatment tool as disclosed in PCT Patent Application Publication No. WO 2016/081951 can change these top surfaces in a subtle way, potentially leading to a higher WLG, which can cause overlay errors. The frictional forces may increase due to the smoothening of the top surfaces of the projections 20 when cleaning with, for example, the treatment tool as disclosed in PCT Patent Application Publication No. WO 2016/081951.

Furthermore, these frictional forces (and thereby the WLG) may increase over time during use; that is, during use the top surfaces of the projections 20 exhibit wear.

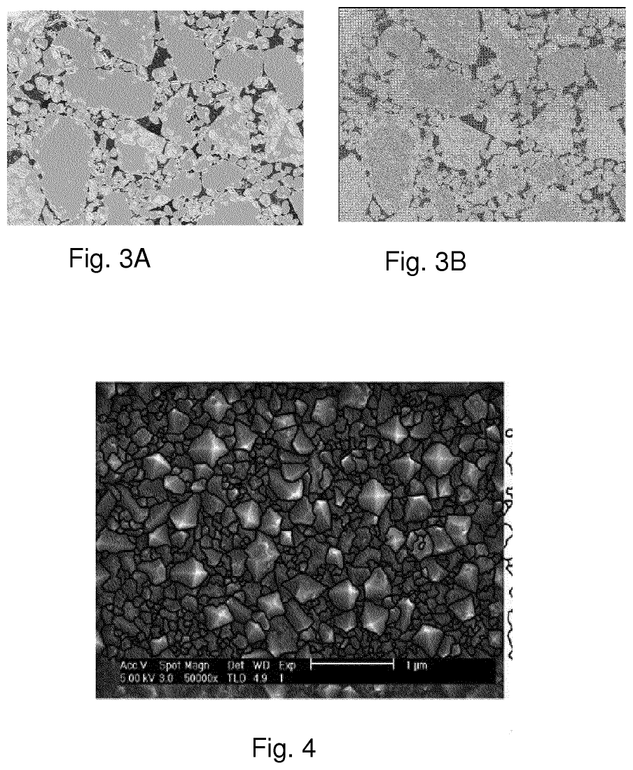

So, in an embodiment, there is provided an improved treatment tool for reconditioning the top surfaces of the projections 20. Such an embodiment of an improved treatment tool comprises a reconditioning surface which is rough relative to the smoothed top surfaces of the projections 20 and which reconditioning surface comprises material harder than that of the material of the top surfaces of the projections 20. A reconditioning interaction between the reconditioning surface of the improved treatment tool and the top surfaces of the projections leaves these top surfaces 20 rougher than they were prior to the reconditioning interaction. The reconditioning interaction can, for instance, be in the form of a movement (e.g. rotation, vibration) creating scratches, or in the form of applying a clamping force creating indentations. After a reconditioning interaction, such as applying a clamping force between the reconditioning surface of the improved treatment tool and the top surfaces of the projections 20, is performed, the top surfaces are slightly rougher due to micro-fracturing of the top surfaces and/or creation of spikes on the top surfaces due to material pile up. FIG. 3A shows a top surface of a projection before a reconditioning interaction and FIG. 3B shows the same top surface after a reconditioning interaction.

In an embodiment the reconditioning interaction is in the form of a piezo induced vibration of the improved treatment tool. Using a piezo element for vibrating the improved treatment tool allows for nanoscale roughness manipulations and reduces or minimizes the debris resulting from a reconditioning interaction.

Roughening the substrate support so that the total contact area between the (projections of the) substrate support and the substrate is reduced will enable lower friction and thereby a lower and more stable WLG.

According to an embodiment, such an improved treatment tool can have a disc- or puck-like shape. According to an embodiment, such an improved treatment tool can take a shape which is compatible with the substrate (wafer) W, such that it can be cycled through the lithographic apparatus as if it was a “standard” substrate.

It is desirable that a pressure (i.e., a force) is applied to the overall contact area between the improved treatment tool and the substrate support, whether for a reconditioning interaction in the form of a movement and/or, especially, for a reconditioning interaction in the form of applying a clamping force.

In an embodiment the reconditioning surface comprises a top layer tailored in roughness and hardness towards re-conditioning the top surfaces of the projections. It is desired that the material of the improved treatment tool is harder than the material of the substrate support so that the substrate support will have plastic deformation (i.e., get rougher) while the improved treatment tool will stay relatively undamaged. For example, a typical hardness of a diamond like carbon (DLC) coating is about 20 GPa. So, the hardness of the reconditioning surface of the improved treatment tool for reconditioning a substrate support with such a coating should therefore be over 20 GPa.

In an embodiment the reconditioning surface comprises a diamond deposited grain structure on top of Si (as shown in FIG. 4) or SiC material or any other compatible ceramic material that contains carbon. In an embodiment such a top layer of the reconditioning surface might take the form of a diamond loaded SiSiC coating with micron level hard asperities. It is noted that the size and distribution of these diamond grains can be adjusted in the improved treatment tool such that the reconditioning of the substrate support is in a controlled way, thus creating the desired roughness of the top surfaces of the projections in the substrate support.

The size of the hard asperities should be such that they help guarantee plastic deformation (i.e., scratching) of the top surfaces of the substrate support. In an embodiment the size of these asperities (or protrusions) is less than 2 μm, desirably less than 0.5 μm.

In an embodiment the spatial density of the asperities is in the range of 1 to 3 per μm². In an embodiment the pitch between the asperities is in the range of 1 to 10 μm. In an embodiment an asperity radius of curvature (i.e., the radius of the top of the asperities) is less than about 0.5 μm, desirably less than about 0.1 μm. It is noted that a low radius is desirable.

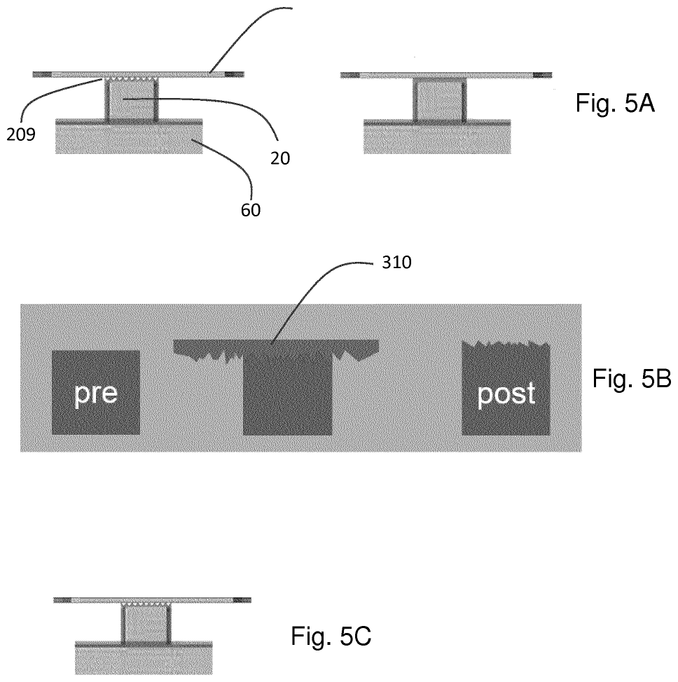

FIG. 5A to 5C schematically illustrate an embodiment of a regeneration method for reconditioning a substrate support 60. The left figure in FIG. 5A shows substrate W supported by a projection 20. The top surface 209 of the projection 20 is still it is original condition (i.e., not affected by wear because of use or by cleaning with a prior treatment tool). The right figure in FIG. 5A shows a top surface of the projection which is affected by wear or cleaning. The top surface in the right figure is significantly smoother than that of the left figure. FIG. 5B shows a reconditioning interaction in which an improved treatment tool 310 having a shape which is compatible with the substrate is clamped (under force) onto the top surface of the projection of the substrate support. After this reconditioning interaction a rougher top surface of the projection remains (as shown in FIG. 5C) resulting in reduced WLG and so a reduced overlay error.

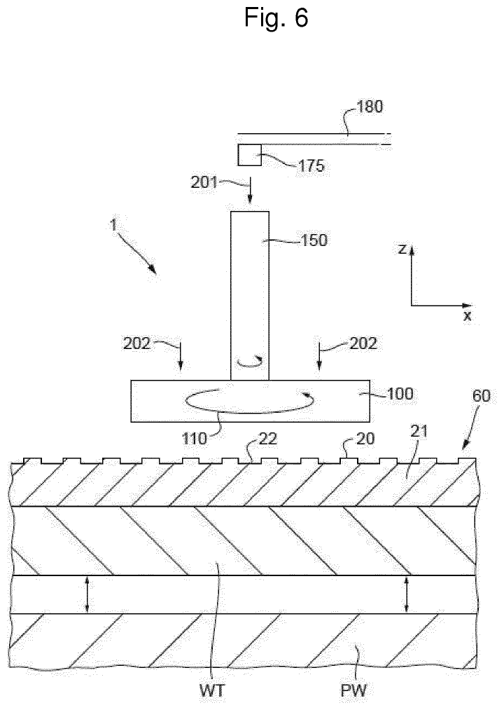

FIG. 6 illustrates schematically a system 1 for reconditioning a substrate support 60. The improved treatment tool 100 is arranged for rotation around the z axis as illustrated by arrow 110. This is effected by rotation of a shaft 150. The treatment tool 100 can contact the top surfaces of the projections 20 of the substrate support 60. Relative translational movement in the x and y directions between the improved treatment tool 100 and the substrate support 60 means that the whole top surface of the substrate support 60 can be moved under the treatment tool 100 such that all projections 20 can be reconditioned. In an embodiment, the system 1 can cause application of a force 202 to the treatment tool 100 such that a pressure is applied by the treatment tool 100 to the substrate support 60. In an embodiment, a fluid 201 can be supplied to the interaction between the treatment tool 100 and the substrate support 60 to, for example, remove material and/or facilitate roughening. In an embodiment, the fluid 201 can be supplied via the treatment tool 100. For example, a surface of the treatment tool 100 may have an opening to dispense the fluid 201. In an embodiment, the fluid 201 is provided to the treatment tool 100 via a nozzle 175 connected to a channel 180 from a source of the fluid 201.

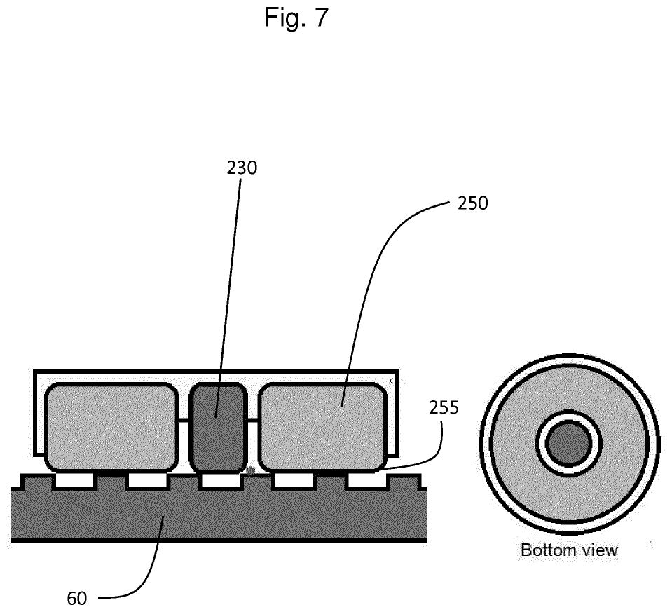

In an embodiment as shown in FIG. 7, the improved treatment tool is of a hybrid kind comprising at least two distinctive parts—a cleaning part 250 configured to remove contamination from the substrate support 60 and a regeneration part 230 configured to reduce the WLG of the substrate support 60. A further part may be added, which further part is intended for restoring the overall flatness of the substrate support. The regeneration part may take the form of any of the embodiments as described before. The cleaning part has a contact surface 255 of a material which is less hard than that of the regeneration part, such as, for example, granite.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools.

While specific embodiments of the invention have been described above, it will be appreciated that the invention may be practiced otherwise than as described.

The descriptions above are intended to be illustrative, not limiting. Thus, it will be apparent to one skilled in the art that modifications may be made to the invention as described without departing from the scope of the claims set out below.

1. A reconditioning device configured to modify the surface of a substrate support, the device comprising a reconditioning surface which is rough relative to the surface of the substrate support, which reconditioning surface comprises material harder than that of the material of the substrate support and which reconditioning surface comprises a layer of a diamond loaded SiSiC coating with micron level hard asperities.

2.-3. (canceled)

4. The device according to claim 1, wherein a spatial density of the asperities is in the range of 1 to 3 per μm².

5. The device according to claim 1, wherein the asperities have a radius of curvature less than 0.5 μm.

6. The device according to claim 1 which is comprised of at least two parts, wherein a first part comprises the reconditioning surface and a second part comprises a cleaning surface of a material less hard than the material of the reconditioning surface.

7. The device according to claim 6, wherein the material of the cleaning surface comprises granite.

8. The device according to claim 1, further comprising an opening in a surface to dispense a fluid.

9. The device according to claim 1, which has the shape and dimensions of a substrate used during standard production.

10. A system for modifying a surface of a substrate support, the system comprising the reconditioning device as claimed in claim 1.

11. A system for modifying a surface of a substrate support, the system comprising a reconditioning device as claimed in claim 8, the system further comprising
a nozzle configured to provide fluid to the opening,
a source of the fluid, and
a channel connecting the nozzle to the source of the fluid.

12. A method for modifying a surface of a substrate support, the method comprising using a reconditioning device to modify the surface of the substrate support, the reconditioning device comprising a reconditioning surface which is rough relative to the surface of the substrate support, which reconditioning surface comprises material harder than that of the material of the substrate support and which reconditioning surface comprises a layer of a diamond loaded SiSiC coating with micron level hard asperities.

13. The method according to claim 12, further comprising causing an interaction between the reconditioning surface of the reconditioning device and end surfaces of a plurality of projections extending from the substrate support.

14. The method according to claim 13, wherein the interaction is a movement of the reconditioning surface relative to the end surfaces of the plurality of projections extending from the substrate support.

15. The method according to claim 13, wherein the interaction is a piezo induced vibration.

16. The method according to claim 13, wherein the interaction is by applying a clamping force between the reconditioning surface and the end surfaces of the plurality of projections extending from the substrate support.

17. The method according to claim 12, further comprising supplying a fluid to the reconditioning device.

18. The method according to claim 12, wherein the reconditioning device is comprised of at least two parts, wherein a first part comprises the reconditioning surface and a second part comprises a cleaning surface of a material less hard than the material of the reconditioning surface and wherein the method comprising using the cleaning surface on the surface of the substrate support.

19. The method according to claim 18, wherein the material of the cleaning surface comprises granite.

20. The method according to claim 12, wherein the reconditioning device has the shape and dimensions of a substrate used during standard production.

21. The method according to claim 12, wherein a spatial density of the asperities of the reconditioning device is in the range of 1 to 3 per μm² and/or a pitch between the asperities is in the range of 1 to 10 μm.

22. The device according to claim 1, wherein a pitch between the asperities is in the range of 1 to 10 μm.
